(19) United States
(12) Patent Application Publication
(10) Pub. No.: US 2013/0093605 A1
(43) Pub. Date: Apr. 18, 2013

(54) SIGNAL GENERATION CIRCUIT FOR KEYBOARDS

(71) Applicants: Ching-Te CHEN, New Taipei City (TW); Chao-Yu HSIAO, New Taipei City (TW)

(72) Inventors: Ching-Te CHEN, New Taipei City (TW); Chao-Yu HSIAO, New Taipei City (TW)

(21) Appl. No.: 13/274,909

(22) Filed: Oct. 17, 2011

(51) Int. Cl. H03M 11/00

(52) U.S. Cl. 341/22

(57) ABSTRACT

A signal generation circuit for a keyboard which includes multiple keys and a signal generation circuit located beneath the keys. Each key is depressible to allow the signal generation circuit to generate a matrix signal. The signal generation circuit includes a matrix circuit layer, an isolation layer located on the matrix circuit layer and a contact layer located on the isolation layer. The matrix circuit layer has a matrix circuit including multiple signal terminals. The isolation layer has multiple apertures corresponding to the signal terminals. The contact layer has at least one connecting circuit which includes multiple impedance terminals formed by mixing metal and carbon powder and a terminal line to form electric connection with the impedance terminals. The impedance terminals oppose to the signal terminals via the apertures and have varying impedances to allow the matrix circuit to generate different matrix signals upon contacting with the signal terminals.

### FIELD OF THE INVENTION

The present invention relates to a signal generation circuit for a keyboard and particularly to a keyboard signal generation circuit with conductive lines doped with carbon powder to change impedance thereof.

### BACKGROUND OF THE INVENTION

Keyboard is one of important tools for communication between input signals and a computer. How to design circuits in the keyboard to mate the computer is a critical factor in keyboard quality. Most conventional circuits under the keys are laid according to a standard keyboard protocol. The keyboard protocol is arranged in series, and each key of the keyboard corresponds to a specific code except the composite keys such as Shift, Ctrl, and Alt. For instance, R.O.C. patent No. 1320939 entitled “Keyboard for eliminating ghost keys” provides a keyboard circuit as shown in its FIG. 1. It has a microprocessor containing a matrix circuit formed with a plurality of parallel and vertical I/O lines connecting to a main level resistor R1. The matrix is crisscrossed to mate a plurality of keys. When a key is depressed, a code representing the key is sent from the keyboard to a computer for interpretation. The keyboard issues a release code upon the pressed key returning to its original condition. One reciprocated action of such operation serves as one key movement.

However, testing the keyboard made according to a set matrix circuit shows that a conflicting phenomenon could still happen even if all elements and wiring of the keyboard are in normal conditions. For instance, when a key is depressed after depressing of another key, the system merely issues the signal of the last key being depressed rather than the signals of the two keys at the same time. This is because the key codes are mutually exclusive. The signal of the previous key is masked without being restored.

There is another phenomenon that when two keys at the corners of the matrix circuit of the keyboard are depressed at the same time, and another key is then depressed, the microprocessor cannot accurately judge the signal of the last depressed key, thus such a phenomenon is commonly called a ghost key. This could cause the problem of missing characters for users who press keys fast. Moreover, as game players often have to press a plurality of keys simultaneously to generate composite key signals to execute different game tactics, the phenomenon of ghost key generated by the keyboard hinders smooth playing of the game.

In order to solve the problem of ghost key that cannot display an effective signal without user's awareness, R.O.C. patent 486661 entitled “Input device with keys defined by multi-dimensional electrodes and coding method thereof” provides a technique to check whether a ghost key (or phantom key) has been depressed, and send back an error signal. Each key is defined by N-dimensional electrodes, where N is an integer greater than 2. It also provides a key scanning method by scanning each dimensional electrode and recording its positional data for comparison to identify the depressed key. Its technique requires alterations of electrodes and scanning process that result in more complex structure. An exclusive signal control IC has to be made for the keyboard, but its production cost is higher. Moreover, the control IC cannot be commonly shared with other keyboards.

### SUMMARY OF THE INVENTION

In view of the number and functions of keys of the keyboard increase constantly, the difficulty and complexity for improving the phenomenon of ghost keys also grow. Moreover, changing the design of a signal control IC or scanning incurs higher cost, and the signal control IC cannot be commonly shared with other keyboards. All these increase the production cost.

Therefore, the primary object of the present invention is to provide a signal generation circuit for a keyboard which includes a plurality of keys and a signal generation circuit located beneath the keys. Each key is depressible onto the signal generation circuit to generate a matrix signal. The signal generation circuit includes a matrix circuit layer, an isolation layer located on the matrix circuit layer and a contact layer located on the isolation layer. The matrix circuit layer has a matrix circuit containing a plurality of signal terminals. The isolation layer is located on the matrix circuit layer and has a plurality of apertures corresponding to the signal terminals. The contact layer has at least one connecting circuit which includes a plurality of impedance terminals formed by mixing metal and carbon powder and a terminal line to form electric connection with the impedance terminals. The impedance terminals oppose to the signal terminals via the apertures and have varying impedances to allow the matrix circuit to generate different matrix signals upon contacting with the signal terminals.

By means of the signal terminals having varying impedances, when the signal terminals are contacted with the impedance terminals, different signals are generated. More specifically, the impedance terminals are respectively formed by mixing a silver compound and carbon powder. The carbon powder can significantly increase the impedance to intensify the electric signal being generated, therefore a greater difference is formed between varying key signals to avoid misinterpretation or generation of ghost keys. Moreover, forming and printing the impedance terminals on the circuit board by adding the carbon powder do not significantly increase the production cost. In addition, altering the composition of the impedance terminals does not need to change the design of the signal control IC, hence the technique of the invention is adaptable to various types of keyboards with the same signal control IC to save production cost.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of the keyboard of the invention.

FIG. 2 is a sectional view of the keyboard of the invention.

FIG. 3 is a fragmentary enlarged view of the contact layer.

### DETAILED DESCRIPTION OF THE PREFERRED EMBODIMENT

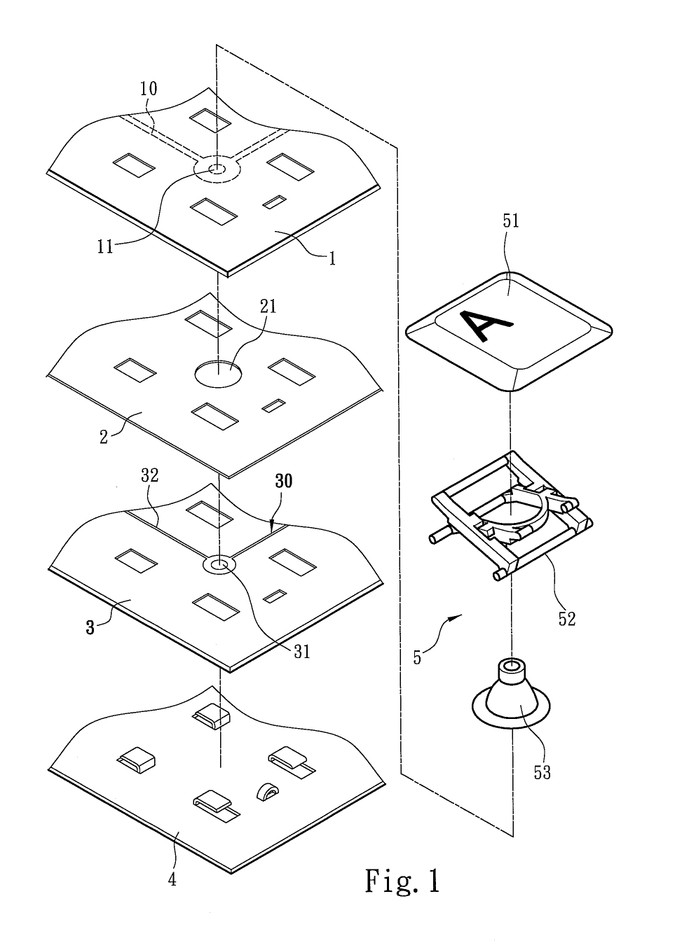

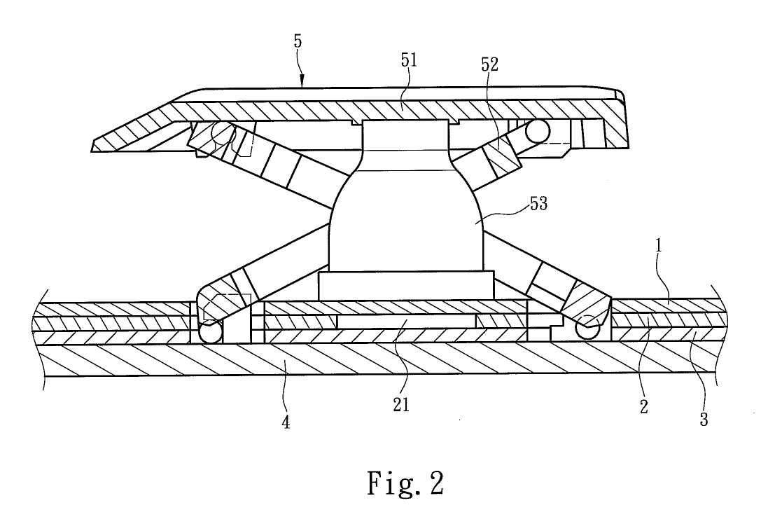

Please refer to FIGS. 1, 2 and 3, the present invention aims to provide a signal generation circuit for a keyboard. The keyboard includes a plurality of keys 5 and a signal generation circuit located beneath the keys 5. Each key 5 includes a key cap 51, a driven mechanism 52 and an elastic element 53. The number of keys 5 and structure thereof are techniques known in the art. Only one key 5 is shown in FIGS. 1 and 2 for illustrative purpose. The keys 5 and signal generation circuit are mounted onto a baseboard 4. The signal generation circuit at least includes a matrix circuit layer 3, an isolation layer 2 and a contact layer 1. The matrix circuit layer 3 is the lowest layer. The isolation layer 2 is located on the matrix circuit layer 3, and the contact layer 1 is located on the isolation layer 2. The keys 5 are located above the contact layer 1. The matrix circuit layer 3 has a matrix circuit 30 formed thereon that includes a plurality of signal terminals 31 and a plurality of signal lines 32 to connect to the signal terminals 31. The signal lines 32 and signal terminals 31 are respectively made of a silver compound. The isolation layer 2 is made of an insulation material to isolate the matrix circuit layer 3 and contact layer 1. The isolation layer 2 has a plurality of apertures 21 corresponding to the signal terminals 31 and located thereon. The contact layer 1 has at least one connecting circuit 10 which includes a plurality of impedance terminals 11 and a terminal line 12 to connect to the impedance terminals 11. When the contact layer 1 is laid on the isolation layer 2, the connecting circuit 10 faces the matrix circuit layer 3 and the impedance terminals 11 also correspond to the apertures 21, hence the impedance terminals 11 and signal terminals 31 are located at two ends of the apertures 21 and oppose to each other via the apertures 21. The impedance terminals 11 are respectively formed by mixing a silver compound and carbon powder. By changing the composition ratio of the carbon powder and the silver compound, the impedance terminals 11 can have varying impedances.

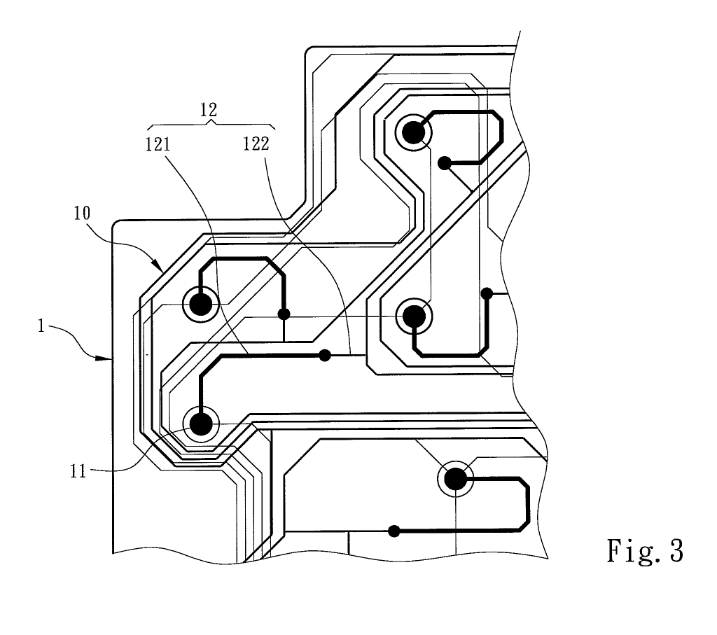

As shown in FIG. 2, the key 5 is located on the contact layer 1 and can be depressed to press the contact layer 1 downwards via the elastic element 53 so that the impedance terminal 11 contacts with the signal terminal 31 to generate a matrix signal to represent the specific key being depressed, and be output to an electronic apparatus electrically connected to the keyboard. Also refer to FIG. 3 for an embodiment of the connecting circuit 10. It includes a plurality of impedance terminals 11 and a terminal line 12 connecting to the impedance terminals 11. As previously discussed, the impedance terminals 11 contain carbon power and have higher impedances. Hence when the impedance terminals 11 are contacted with the signal terminals 31, varying matrix signals with obvious differences are generated. Moreover, because the impedance terminals 11 have varying impedances, the matrix signals generated can be identified and differentiated easier. Furthermore, the terminal line 12 is divided into at least one high impedance section 121 formed by mixing metal and carbon powder and at least one low impedance section 122 made of metal. The metal used in the high impedance section 121 and low impedance section 122 is a silver compound. In FIG. 3, the high impedance section 121 is formed thicker than the low impedance section 122 to facilitate differentiation. The high impedance section 121 has one end connected to the impedance terminal 11 and another end connected to the low impedance section 122 so that the impedance terminal 11 and the high impedance section 121 are collaborated to generate different matrix signals with obvious differences, thereby can improve the phenomenon of ghost keys.

While the invention has been described by means of specific embodiments, numerous modifications and variations could be made thereto by those skilled in the art without departing from the scope and spirit of the invention set forth in the claims.

In summation of the above description, the present invention provides a significant improvement over the conventional techniques and complies with the patent application requirements, and is submitted for review and granting of the commensurate patent rights.

What is claimed is:

1. A signal generation circuit for a keyboard which includes a plurality of keys and a signal generation circuit located beneath the plurality of keys each being depressible to connect to the signal generation circuit to generate a matrix signal, the signal generation circuit comprising:
a matrix circuit layer including a matrix circuit which includes a plurality of signal terminals;
an insulating isolation layer which is located on the matrix circuit layer and includes a plurality of apertures corresponding to the plurality of signal terminals; and
a contact layer which is located on the isolation layer and includes at least one connecting circuit which includes a plurality of impedance terminals formed by mixing metal and carbon powder and a terminal line to form electric connection with the plurality of impedance terminals, the impedance terminals opposing to the signal terminals via the plurality of apertures and including varying impedances to allow the matrix circuit to generate different matrix signals upon contacting with the signal terminals.

2. The signal generation circuit of claim 1, wherein the impedance terminals are respectively formed by mixing a silver compound and the carbon powder.

3. The signal generation circuit of claim 2, wherein the silver compound and the carbon powder are mixed at varying ratios to allow the impedance terminals to include the varying impedances.

4. The signal generation circuit of claim 1, wherein the terminal line includes at least one high impedance section formed by mixing the metal and the carbon powder and at least one low impedance section made of the metal.

5. The signal generation circuit of claim 4, wherein the high impedance section is connected to the impedance terminal.

6. The signal generation circuit of claim 4, wherein the metal of the high impedance section and the low impedance section is a silver compound.

7. The signal generation circuit of claim 1, wherein the matrix circuit further includes a plurality of signal lines to connect to the signal terminals, the signal lines and the signal terminals being respectively made of a silver compound.
